(19) United States
(12) Patent Application Publication
(10) Pub. No.: US 2026/0280493 A1
(43) Pub. Date: Sep. 17, 2026

(54) DIGITAL OFFSET REJECTION MECHANISM

(71) Applicant: Allegro MicroSystems, LLC, Manchester, NH (US)

(72) Inventors: Steven Daubert, Bedford, NH (US); Srujan Shivanakere, Nashua, NH (US); Tyler Daigle, Scarborough, ME (US)

(73) Assignee: Allegro MicroSystems, LLC, Manchester, NH (US)

(21) Appl. No.: 19/075,997

(22) Filed: Mar. 11, 2025

(51) Int. Cl. H03F 1/30; H03M 1/06

(52) U.S. Cl. CPC H03F 1/304; H03M 1/0626

(57) ABSTRACT

This disclosure describes circuitry to improve the cancellation of the input-referred offset in the opamp of a sensor front end by implementing a feedback path around the opamp in the digital domain. This implementation uses an A/D converter, a digital integrator and a D/A converter. The A/D converter can be a 1-bit converter constructed with a comparator. The performance of the comparator can be improved by using a chopping technique. The integrator can be initialized upon power-up to a state from a previous measurement, dramatically reducing the convergence time. The gain of the feedback path can be adjusted, which lowers or raises a low frequency pole. Lowering the gain lowers the pole frequency and improves the low frequency response of the transducer path. The low frequency pole can be set track the slowly varying opamp offset.

### BACKGROUND

Previously described mechanisms for current sensor feedback use Proportional-Integral (PI) feedback implemented using external or on-chip components. For example, the integrator may have been implemented using an operational amplifier (opamp), resistors and capacitors. Such mechanisms set the feedback low pass filter frequency as low as possible to widen the signal pass band. When on chip components are used, the low pass frequency is usually limited by the size of resistors and capacitors that are accommodated on the chip. This limitation leads to a parasitic pole in the loop of coil front end of inductive sensors that eventually shows up as a ripple in overall frequency response of the chip.

One method of current sensing uses an on-chip coil to sense a magnetic field that has been created by the current to be sensed. This coil is connected to an integrator or a lowpass filter to create a constant frequency response. With this approach, an opamp is used to provide the gain for the integrator or lowpass filter. The opamp, however, has an input-referred offset that, if not eliminated, can saturate the output of the integrator/lowpass filter. This offset can be eliminated by using a feedback path around the integrator/lowpass filter.

Previous work, such as in U.S. Pat. No. 11,366,141 (which is incorporated by reference in its entirety) discloses using PI feedback as an offset rejection circuit implemented in RC networks.

### SUMMARY

This disclosure describes circuitry to improve the cancellation of the input-referred offset in the opamp of a sensor front end by implementing a feedback path around the opamp in the digital domain. This implementation uses an A/D converter, a digital integrator and a D/A converter. The A/D converter can be a 1-bit converter constructed with a comparator. The performance of the comparator can be improved by using a chopping technique. The integrator can be initialized upon power-up to a state from a previous measurement, dramatically reducing the convergence time. The gain of the feedback path can be adjusted, which lowers or raises a low frequency pole. Lowering the gain lowers the pole frequency and improves the low frequency response of the transducer path. The low frequency pole can be set high enough, though, to track the slowly varying opamp offset.

In one aspect, a semiconductor device improves frequency cross over ripple and uses a smaller area and achieves faster start up time than conventional devices. The semiconductor device includes at least one magnetic field sensing element. The semiconductor device also includes a first signal path acting as a low pass filter. The first signal path has an opamp coupled to the at least one magnetic field sensing element. The opamp receives an input voltage and generates a low frequency signal. The semiconductor device also includes a second signal path operating as a filter for offset rejection. The second signal path includes a digital integrator and a DAC. The DAC is configured to receive a signal from the digital integrator and provide an analog signal. The second signal path receives the low frequency signal as input and generates the analog signal as an offset rejection signal. The offset rejection signal is coupled in a feedback relationship to the input voltage.

The digitizer may include a 1-bit analog to digital converter (ADC). The 1-bit ADC may include a comparator.

The offset rejection filter may also include a memory to store an indication of a previous output value of the digital integrator. The memory can also store an integration gain, Ki and/or a sampling period, Ts.

The DAC can provide increased resolution using oversampling and PWM. The DAC may be a 10-bit DAC or a 14-bit DAC (or other resolutions).

The semiconductor device may also include transducer coils to generate the input voltage.

The amplifier may receive the input signal generated by one or more magnetic field transducers.

The semiconductor device may include a current sensor. The current sensor includes an IC package.

The semiconductor device may be part of an electronic system, for example, a microchip or a digital device. The semiconductor device may be embodied in an integrated circuit (IC), for example, but not limited to, a magnetic field sensor IC, or a current sensor IC.

According to another aspect, a method for is described. The method includes receiving an input signal at an amplifier. The amplifier generates an amplified signal based on the input signal. The method also includes receiving the amplified signal at an offset rejection filter. The offset rejection filter digitizes the amplified signal to produce a digitized signal; digitally integrates the digitized signal to produce an integrated signal; and converts the integrated signal to an analog feedback signal. The method also includes receiving the analog feedback signal back at the amplifier. Generation of the amplified signal is also based on the analog feedback signal.

The offset rejection filter may include a 1-bit analog to digital converter (ADC) configured to digitize the amplified signal. The 1-bit ADC may include a comparator.

Digitally integrating the digitized signal may be based, at least in part on, a previous output value of the digital integrator.

The offset rejection filter may include a 10-bit DAC or a 14-bit DAC configured to convert the integrated signal.

The method may also include sensing a current in a circuit to produce the input signal. The current may be sensed by transducer coils.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 illustrates a circuit having offset rejection feedback.

FIG. 2 is a prior-art proportional-integral circuit.

FIG. 3 illustrates a circuit having a filter for offset rejection.

FIG. 4A is a graph of DAC output with pulse-width modulation.

FIG. 4B is a graph of DAC input code associated with the DAC output of FIG. 4A.

FIG. 5 is a graph of comparing voltage over time for two circuits and showing the faster settling of Vout when the digital integrator is initialized.

FIG. 6 shows the frequency response for different values of Kᵢ.

### DETAIL DESCRIPTION

Described herein are techniques to provide a digital offset rejection mechanism for an amplifier. In one non-limiting embodiment, the digital offset rejection mechanism is used in a high bandwidth current sensor. The digital offset rejection mechanism can also be applied to any front end in order to provide offset cancellation.

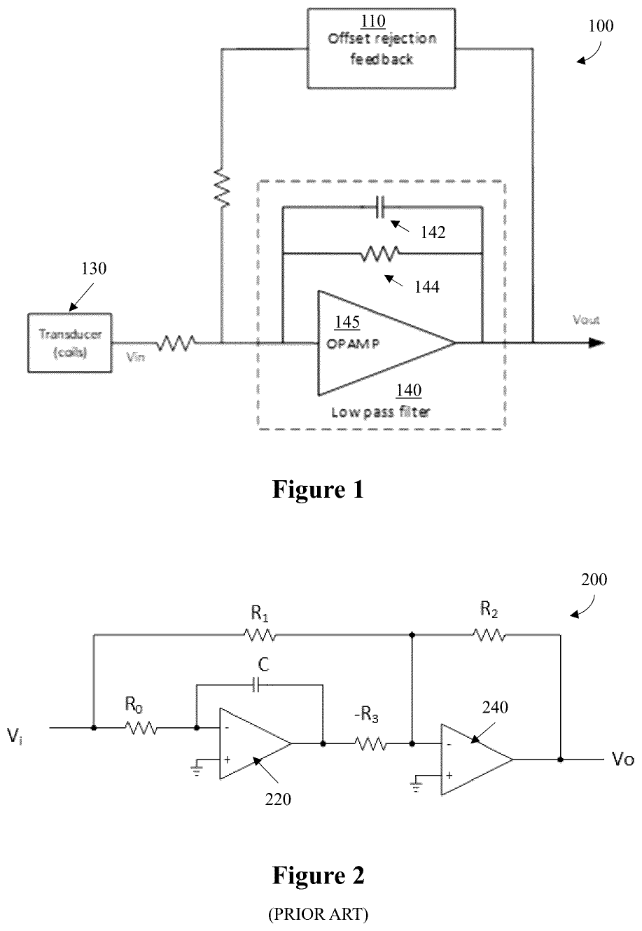

FIG. 1 illustrates a circuit 100 having digital offset rejection for an amplifier in accordance with various embodiments. The circuit includes a transducer 130 which provides the input voltage, Vᵢₙ. A low pass filter 140 and the offset rejection feedback component 110 are connected to the Vᵢₙ. and the output voltage, Vₒᵤₜ. The low pass filter 140 includes an opamp 145, a capacitor 142 and a resistive element 144.

The transducer 130 may be a transducer coil. In some embodiments, the transducer 130 may also include or be replaced with one or more magnetic field sensing elements, which may include, but are not limited to a Hall effect transducer or a magnetoresistance sensor, such as a Tunnel Magnetoresistance (TMR) element or a magnetic tunnel junction element (MTJ).

In contrast with the example traditional device shown in FIG. 2, various embodiments of the disclosure replace the analog RC-opamp integrator design with a digital integrator. This allows longer time constants to be implemented digitally. Additionally, the digital integrator avoids the large amount of chip area used by relatively large RC components. A digital integrator can be used to provide flexibility to change the time constants dynamically depending on the condition of the chip. For example, the time constants can be adjusted during power on of the chip for faster stabilization of the loop. The circuit may also include a memory so that a previously used integrator value can be stored and recalled during power on for further reduction in start-up time.

Due to the relatively large size of RC components in conventional offset rejection circuits, it is difficult to achieve the long time constants needed to implement low pass poles below 1 KHz. In one non-limiting embodiment, usable high frequency signals in the signal path may be limited to being 2 decades higher than the low pass pole of the PI feedback. This ensures a ripple free frequency response at the sensor's output. For example, a switched-capacitor circuit may be used to realize a large effective resistor R₀.

FIG. 2 illustrates a conventional PI circuit 200 (such as, that described in U.S. Pat. No. 11,366,141). The PI circuit 200 is shown as a single-ended PI circuit implementation with the signal inversion by a negative resistance −R₃. The PI circuit 200 also includes an input resistor R₀. In other aspects, PI circuit 200 includes an integral stage including an operational amplifier 220 and a feedback capacitor C and a proportional stage including an operational amplifier 240. Proportional amplifier 240 has a feedback resistor R₂ and uses the negative resistance, −R₃, as an input resistor.

Various embodiments, such as the embodiment shown in FIG. 1, can operate with significantly longer time constants using a digital integrator without a large chip area as would be needed for a traditional circuit such as the embodiment shown in FIG. 2. Embodiments having a digital integrator in the offset rejection circuit can provide faster start up response and quicker stabilization of the loop.

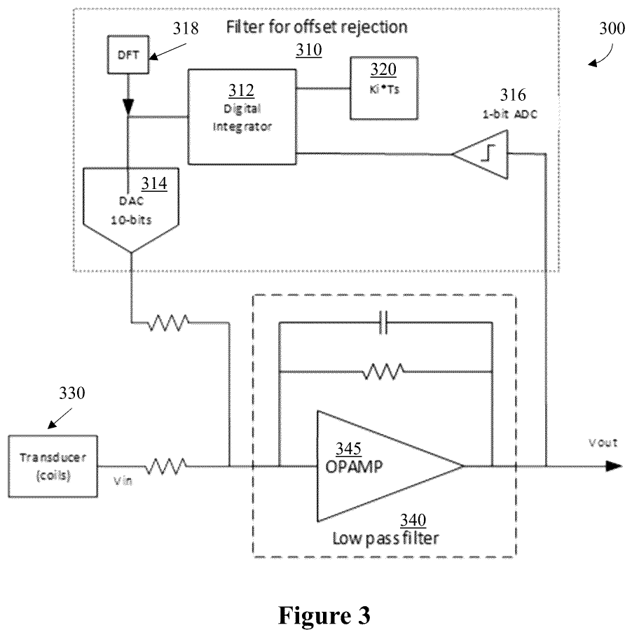

In another embodiment, shown in FIG. 3, a feedback circuit 300 includes a filter for offset rejection 310. In an example embodiment, the filter for offset rejection 310 has a 1-bit ADC 316, a DAC 314 and a digitally programmable integrator 312 with a memory 320 storing constants representing a gain in integration, Kᵢ, and a period, Tₛ. The 1-bit ADC 316 can be realized using a comparator. It is understood that any suitable circuit can be used to convert the analog amplifier output to a digital signal.

The DAC code may be pulse width modulation (PWM) encoded to shape quantization noise and push it to higher frequencies. It is understood that any practical mechanism can be used to generate codes for controlling the DAC 314. This arrangement allows for attenuation in the front-end integrator. The DAC 314 may be configured for injection of test signals at the input of front end via a signal injection module 318. Additionally, the DAC may increase the resolution using oversampling.

In an alternative embodiment, the ADC may be realized using a multibit architecture. This ADC can be chopped to further reduce offsets in the loop. The ADC may be realized as any appropriate digitizer configured to receive a signal in an analog domain and provide an output in a digital domain.

Digital integration by the digital integrator 312 provides the flexibility to change the time constants dynamically depending on the condition of the chip. Digital integrator parameters, such as constants Kᵢ and Tₛ, can be adjusted during trimming and power on of the chip for faster integration and stabilization of the DAC output to final value. The memory 320 may also store other values that can be recalled during power on for further reduction in start-up time, such as a previously used DAC value (e.g., the integrator output) for each chip.

To increase the effective number of DAC bits, the digital integrator 312 can digitally encode the DAC least significant bit (LSB) using a pulse width or pulse density modulation scheme. The number of added effective DAC bits may depend on the resolution of the encoding and the desired digital frame.

In some implementations, the feedback loop can be sampled at a clock rate of 16 MHz. Using a digital frame rate of 16 clocks to encode the DAC word, the DAC's LSB will be increased by 16×, which is equivalent to adding 4 bits. This results in a frame clock, f-frame, of 1 MHz. The overall spectral result is noise shaping: the effective quantization noise of the added 4 bits appears as tones in the DAC output at f-frame plus all harmonics. Pushing the quantization noise to higher frequencies (above the low-pass filter corner) allows for more attenuation in the signal path's low pass filter.

The DAC 314 may also be used to improve signal path testability (e.g., using DFT 318). This is achieved by introducing a test signal (triangular, square, or sine wave) via the DFT 318 at the output of digital integrator 312. The test signal may be superimposed on top of offset rejection integrator 312 output. In embodiments, both amplitude and period of the signal are programmable. The test signal, which is at a higher frequency, is not attenuated by the digital DC feedback loop.

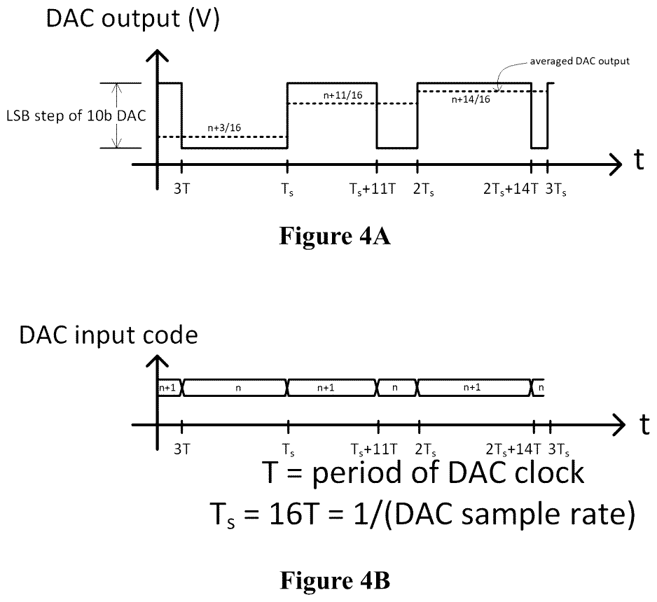

FIG. 4A is a graph of an example DAC output and FIG. 4B is a graph of an example DAC input code associated with the DAC output of FIG. 4A. As shown, the effective number of DAC bits is increased from 10 (for a traditional integrator) to 14. In FIG. 4A, the DAC output is a square wave having a step representing the LSB of the 10-bit input code. The DAC has a sampling rate, Tₛ, which means the input code is sampled 16 times for each input word. The samples are performed each period of the DAC clock, T. Based on the value of the input word, for example, a value of ‘3’, the DAC provides an output having the higher LSB value for that number of clock periods. As shown, a value of 3 has the higher value for 3T and the lower value for the remaining 13T. This provides an averaged DAC output of 3/16.

FIG. 4B shows the DAC input, which switches from n+1 and n after a number of clock periods equal to the input word's value (e.g., 3T, 11T and 14T). Accordingly, the 10-bit DAC's LSB is able to generate a value from 0 to 16, which is equal to a 4-bit number.

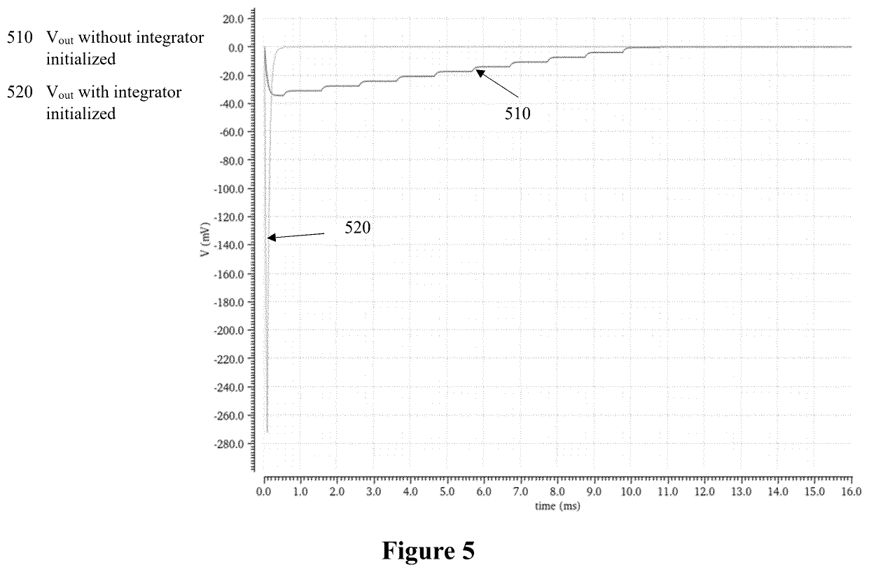

As shown in FIG. 5, faster startup is possible with digital implementation. Both curves 510, 520 show the output, Vₒᵤₜ, with zero input following power up. Since the opamp has a small input offset, the output is not initially at 0V. The curve with the integrator initialized 520 uses a previously measured value to cancel the offset shows Vₒᵤₜ reaching the desired 0V in about 1 ms and continues with that value. In contrast, the curve without the initialization 510 shows the output doesn't reach 0V until 11 ms. As shown, both curves extend out to 16 ms for clarity.

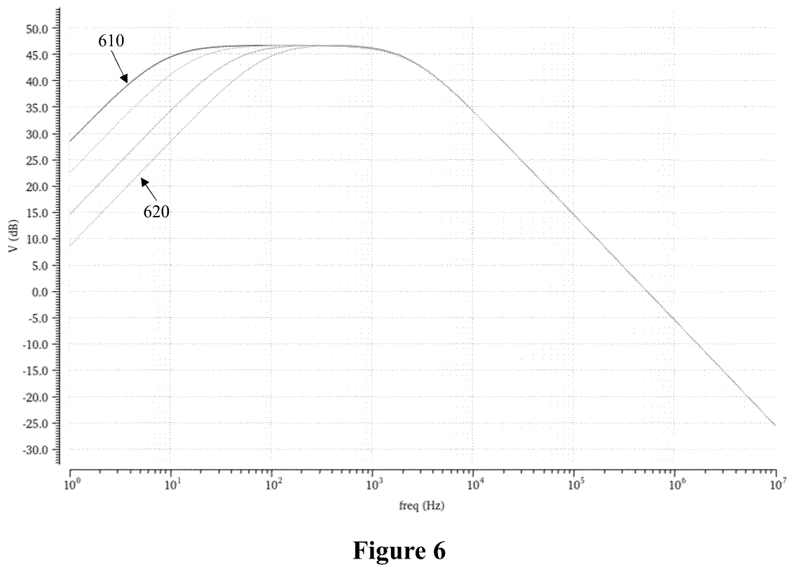

Changing the value of Kᵢ in the digital feedback can be used to change the frequency response from the transducer input, Vᵢₙ, to the output, Vₒᵤₜ, as shown in FIG. 6. FIG. 6 shows the frequency response for different values of Kᵢ, with a lower Kᵢ creating a lower frequency corner. By changing Kᵢ from a larger value (curve 620) at power-up to a smaller value (curve 610) in steady-state, the system more quickly converges to the correct value for offset cancellation. Following start-up, the lower Kᵢ improves to overall frequency response, allowing low frequency signals from the transducer to pass.

Having described preferred embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. An integrated circuit, comprising:
at least one magnetic field sensing element configured to generate an input signal;
an amplifier coupled to the at least one magnetic field sensing element, the amplifier configured to provide a low pass filter;
an offset rejection filter coupled in a feedback arrangement with the amplifier for reducing an offset of the amplifier, the offset rejection filter comprising:
a digitizer coupled to an output of the amplifier;
a digital integrator coupled to an output of the digitizer; and
a DAC having an input coupled to an output of the digital integrator and an output coupled to an input of the amplifier.

2. The integrated circuit of claim 1, wherein the digitizer comprises a 1-bit analog to digital converter (ADC).

3. The integrated circuit of claim 2, wherein the 1-bit ADC comprises a comparator.

4. The integrated circuit of claim 1, wherein the offset rejection filter further comprises a memory configured to store an indication of a previous output value of the digital integrator.

5. The integrated circuit of claim 4, wherein the memory is further configured to store an integration gain, Kᵢ.

6. The integrated circuit of claim 4, wherein the memory is further configured to store a sampling period, Tₛ.

7. The integrated circuit of claim 1, wherein DAC is one of: a 10-bit DAC, and a 14-bit DAC.

8. The integrated circuit of claim 1, wherein DAC is pulse width modulation (PWM) encoded.

9. The integrated circuit of claim 1, wherein the at least one magnetic field sensing element comprises transducer coils.

10. The integrated circuit of claim 1, wherein the at least one magnetic field sensing element comprises at least one of: a Hall Effect element, a magnetoresistance element, and a tunneling magnetoresistance element (TMR).

11. The integrated circuit according to claim 1, wherein the at least one magnetic field sensing element comprises a current sensor.

12. The integrated circuit according to claim 11, wherein the current sensor is embodied in an IC package.

13. A method, comprising:
using at least one magnetic field sensing element to generate an input signal;
receiving the input signal at an amplifier;
using the amplifier to generate an amplified signal based on the input signal;
receiving the amplified signal at an offset rejection filter, the offset rejection filter configured to:
digitize the amplified signal to produce a digitized signal;
digitally integrating the digitized signal to produce an integrated signal; and
converting the integrated signal to an analog feedback signal; and
receiving the analog feedback signal at the amplifier, wherein generating the amplified signal is further based on the analog feedback signal.

14. The method of claim 13, wherein the offset rejection filter comprises a 1-bit analog to digital converter (ADC) configured to digitize the amplified signal.

15. The method of claim 14, wherein the 1-bit ADC comprises a comparator.

16. The method of claim 13, wherein digitally integrating the digitized signal is based, at least in part on, a previous output value of the digital integrator.

17. The method of claim 13, wherein the offset rejection filter comprises one of: a 10-bit DAC configured to convert the integrated signal, and a 14-bit DAC configured to convert the integrated signal.

18. The method of claim 13, wherein the offset rejection filter is pulse width modulation (PWM) encoded.

19. The method of claim 13, further comprising sensing a current in a circuit using the at least one magnetic field sensing element.

20. The method of claim 19, wherein sensing the current is performed by at least one of: transducer coils, a magnetoresistance element, and a tunneling magnetoresitance element (TMR).
